(19) United States
(12) Patent Application Publication
(10) Pub. No.: US 2009/0181249 A1
(43) Pub. Date: Jul. 16, 2009

(54) PAPER SUBSTRATE COMPRISING VAPOUR DEPOSITED TRIAZINE, AND PROCESS FOR MAKING A LAMINATE COMPRISING SAID SUBSTRATE

(76) Inventor: Shahab S. Jahromi, Maastricht (NL)

Correspondence Address: NIXON & VANDERHYE, PC, 901 NORTH GLEBE ROAD, 11TH FLOOR, ARLINGTON, VA, 22203, US

(21) Appl. No.: 12/296,592

(22) PCT Filed: Apr. 3, 2007
(86) PCT No.: PCT/EP2007/002980

§ 371 Date: Oct. 9, 2008

(30) Foreign Application Priority Data
Apr. 13, 2006 (EP) 06007807.8

(51) Int. Cl. B32B 29/00; C23C 16/00; B29C 53/00

(52) U.S. Cl. 428/340; 428/537.5; 428/211.1; 427/255.6; 264/257

(57) ABSTRACT

The invention relates to paper substrates comprising vapor deposited triazine, the amount of crystalline triazine being about g/m² or higher, and about 100 g/m² or lower. The invention also relates to a process for making a laminate comprising at least one cured layer of melamine-formaldehyde resin and a paper, wherein a) triazine is deposited on paper with vapor deposition, to obtain a paper substrate comprising vapor deposited triazine, b) the triazine-deposited paper is either impregnated with a formaldehyde solution, or a melamine formaldehyde resin having an F/M ratio of 1.5 or higher, or the triazine-deposited paper is laid adjacent to an impregnated sheet with a melamine formaldehyde resin having an F/M ration of 1.5 or higher, or b′) one or more layers of said triazine-deposited paper are laid in a press, together with one or more other layers to have a stack of papers, and formaldehyde is injected into the press c) in such amounts that the composite F/M ratio is 1.6 or lower d) submitting the paper with one or more other layers to pressure and/or sufficient temperature to cure the triazine and resin.

The invention relates to a process for making a laminate, in particular a decorative laminate. The laminate comprises at least one cured layer of preferably melamine-formaldehyde resin and paper, preferably paper with a color or pattern (decor).

Decorative laminates are much used in the building and furniture industry. Such products have a cladding of highly abrasion resistant cured resin, which furthermore has high resistance against chemicals and moisture. Generally, these products comprise cured resin and fibrous material. Generally the laminates are made from decorative paper, impregnated with melamine-formaldehyde resin, which are cured by heat and pressure on one or more base sheets. For example, particle or card board can be covered with one or more melamine-formaldehyde resin impregnated paper sheets, which are subsequently cured by heat and pressure. In another example, melamine-formaldehyde resin impregnated papers are put on top of a stack of phenol-formaldehyde resin impregnated kraft papers and subsequently cured. Melamine-formaldehyde resins are for example described in EP-A-0561432.

Three often used methods for making final laminates are known: Low Pressure Laminate (LPL), High Pressure Laminate (HPL) and Continuous Pressure Laminate (CPL). Low pressure is most often used with card-board or particle board, whereas high pressure generally is used with the so-called kraft papers. The sheets, or products resulting from the HPL-process are generally not self-supportive. In general, they are bonded, with a suitable adhesive or glue, to a rigid substrate such as particle board or medium density fiber board (MDF). In a continuous pressure laminate process, papers are fed from a role into a continuous belt press.

Current production suffers from drawbacks which are not easily overcome. One problem is that the laminates made in the high pressures or continuous process are so hard, that it is difficult to bend or ‘post-form’ these sheets. Yet, it would be an advantage if—while keeping the abrasion resistance and chemical resistance properties—the HPL or CPL sheets would be bendable, so they could be made to cover e.g. MDF boards not only on one side, but in one process step, also one or more of the other sides. At present, post-forming characteristics are often achieved by either incorporating expensive modifiers like benzoguanamine or acetoguanamine (as for example described in EP-A-0561432), or by making melamine-formaldehyde resins at high pressure, allowing more melamine to react with formaldehyde. The latter process is relatively expensive, and requires high pressure vessels. Another drawback is the use of formaldehyde, which is known to be a toxic chemical. The resin used to impregnate paper is basically a formaldehyde-melamine resin. After cure, the laminate still releases some formaldehyde, which may cause environmental concerns. Furthermore, the resin that is used for impregnating the paper has as a drawback that its stability is limited—generally—to about one month. Obviously, making the resin adds a production step, which is a disadvantage by itself. Another disadvantage is the limited use that can be made of triazines other than melamine. One other triazine-type compounds that should be useful in making laminates with improved post-forming characteristics is for example melam.

One object of the invention is to provide paper sheets, suitable for laminates with low formaldehyde emission and/or good post forming characteristics, and that could obviate the use of resin altogether.

Another object of the invention is a paper, impregnated with resin, suitable for laminates with low formaldehyde emission and/or improved post forming characteristics.

Another object of the invention is a process for making a laminate with improved low formaldehyde emission and/or post-forming characteristics.

These objects and other advantageous features are achieved with the present invention, whereby a paper substrate is subjected to vapor deposition of triazine, to obtain a vapor-deposited crystalline-triazine paper with an amount of crystalline triazine being about 5 g/m² or higher, and about 100 g/m² or lower.

The vapor deposition will yield crystalline triazine. Crystalline is here used in the sense that with scanning electron microscopy it is possible to see triazine crystals at a magnification of ten to the sixth. (1 cm is 10 nm).

Suitable triazines for vapor deposition include, but are not limited to, melamine, melam, acetoguanamine, benzoguanamine, dicyanediamine, toluenesulphonamide and urea. Preferred examples are melamine and urea, because of cost reasons.

In one embodiment, it is preferred to use melamine as the triazine compound for vapor deposition, as that is a widely available material and gives very good characteristics. In practice, it appears difficult to make resins with melam, so use of these materials in laminates has been very limited. The present invention obviates the step of making a resin at least in part. Thereby, it now becomes easily possible to make laminates which comprise melam in the ultimate cured resin.

In one embodiment of the invention, a mixture of triazines is used for vapor deposition, in another embodiment of the invention, two or more triazines are vapor deposited consecutively, from different vapor deposition vessels. This may be advantageous over the use of mixtures, as far as the sublimation temperature varies for the different triazines.

In one embodiment of the invention, both sides of paper have vapor deposited triazine.

The majority of laminates is made with paper. Some laminates are made from non-woven fibrous material with paper-like characteristics, like non-woven glass fibers, carbon fibers, natural fiber or polymeric fiber cloth or blends of these materials. In the present invention, the word paper is used to comprise other non-woven materials, unless specifically defined.

In one embodiment, it is preferred to use paper, consisting of non-woven and non-spun cellulose fiber.

In one embodiment, the paper is a decorative paper. The decoration preferably is a printed décor, and may be representing a wood structure. In another embodiment, the décor paper is a plain color, like white. In another embodiment, the decor represents granite, marble or other naturally occurring materials. The printing ink may be for example an alkyd based ink, or a polyester acrylate based ink.

In another embodiment, the paper is suitable as so-called overlay paper. Overlay papers are highly transparent when impregnated and cured, and are used as scratch resistant top layer applied on top of a decorative paper. Often, overlay papers are used in laminate manufacturing for wood panels for flooring.

The printed paper preferably has a weight of about 15 g/m² or more, preferably of about 70 g/m² or more. Generally, the paper will have a weight of about 200 g/m² or less, preferably of about 150 g/m² or less. Such paper types do provide an optimum appearance of the resultant decorative panel, but also a good penetration power of the resin. The overlay paper generally has a weight of about 10 g/m² or more, preferably about 15 g/m² or more, and generally a weight of about 60 g/m² or less, preferably about 40 g/m² or less.

In another embodiment of the invention, the paper is colored, which is achieved by vapor deposition of at least one organic dye, together with the triazine deposition, or in a vapor deposition chamber next to the triazine vapor deposition chamber.

The amount of triazine on the paper is generally about 5 g/m² or more, and preferably about 10 g/m² or more. An even smaller amount of triazine like for example about 1 g/m² or about 3 g/m² or more still may be advantageous because an increase in amount of melamine is preferred, but its added value is lower.

The amount of triazine on the paper is generally about 100 g/m² or less, preferably about 90 g/m² or less. Higher amounts may cause difficulties with processing the triazine comprising paper. If may become more difficult to dissolve all triazine in the curing step, assuming that is a requirement.

The vapor deposition of triazine on the paper substrate can be performed as described in U.S. Pat. No. 6,632,519, WO 2004/101882 and WO 2004/101843, which disclosures are herewith incorporated by reference. The triazine layers deposited according these references generally are thin (e.g. 100 nm), leading to low amounts of triazine per square meter of substrate. The vapor deposition preferably is carried out in a vacuum chamber, at reduced pressure. Preferably, the deposition is performed in an inert atmosphere, like for example a nitrogen atmosphere. Preferably, the vapor deposition process takes place in a vacuum chamber having a pressure of about 1.0 mbar or less, preferably of about 1 mbar or less, and more preferably of about 10⁻³ mbar or less. The pressure will generally be about 10⁻⁵ mbar or higher, but the low end mainly follows economic and practical considerations. In general, the triazine will be heated. The required temperature for sublimation is dependent on the vacuum, and is preferably about 150° C. or higher, preferably about 200° C., even more preferred about 300° C. Generally, the temperature to heat the triazine will be close to the decomposition temperature, which is different for each triazin. For melamine, the temperature will be about 350° C. or lower. For melam, the temperature will be about 450° C. or lower. Generally, to achieve a reliable vapor deposition of the triazine. It is preferred to keep the substrate at a temperature that is about 100° C. lower than the temperature for heating the triazine, preferably, the temperature difference is about 200° C. or more, and even more preferred, about 300° C. or more. Preferably, the substrate is kept at about room temperature, e.g. at a temperature of about 20° C. Some heating will occur during the deposition step, but this is not critical. The amount of triazine deposited can be steered by the amount of time the paper is subjected to the vapor deposition, the concentration of the triazine in the vapor (which is dependent a.o. on the temperature the triazine is heated and the pressure).

In one embodiment of the present invention, the speed of the paper over the vacuum chamber is about 0.5 m/s or more. The speed generally will be about 10 m/s or less. The temperature of the triazine in the vacuum chamber has a temperature of about 250° C. or higher, preferably about 330° C. or higher. The vacuum is preferably about 10⁻⁴ mbar or less.

It is possible to perform the vapor deposition during up to a few minutes, but this generally will not be economically attractive. An advantage of high speed, high vacuum, high vapor concentration deposition, with a temperature difference of triazine and the substrate of about 250° C. or more is, that triazine is deposited as a very microcrystalline layer, which improves the dissolution during lamination process substantially.

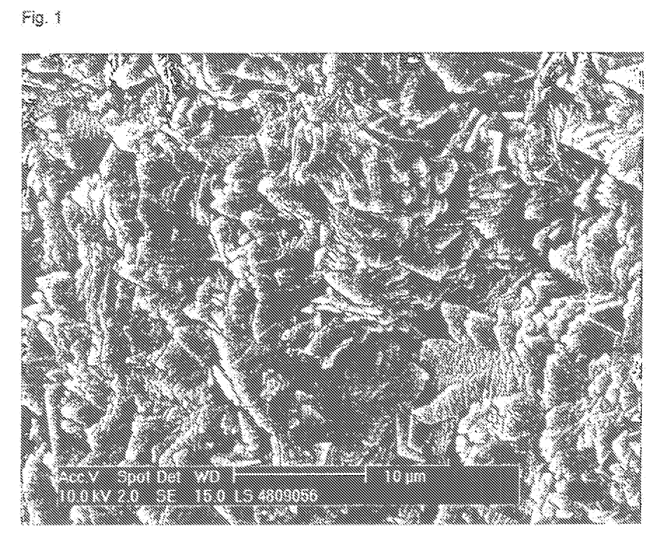

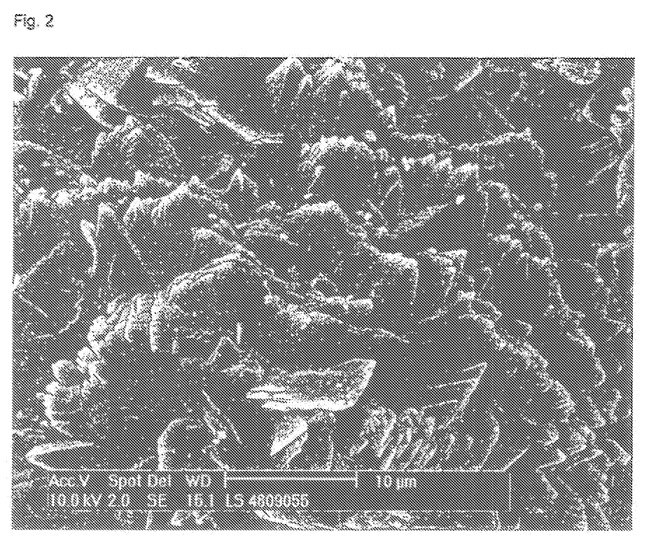

Therefore, the triazine on the paper substrate with deposited triazine preferably will have a microcrystalline structure. On a SEM photograph, the crystal size of melamine preferably shows as mulls crystalline platelets. The platelets generally will have a width of about 100 μm or less, more preferably about 50 μm or less. Generally, the width will be about 20 nm or more, preferably about 50 nm or more. Generally, the thickness of the platelets will be about 10 μm or less, preferably about 5 μm or less. Generally, the thickness will be about 1 nm or more, preferably about 5 nm or more. FIG. 1 is a photograph of vapor deposited melamine on paper. The amount of melamine is 17 g/m². FIG. 2 is a photograph of vapor deposited melamine, whereby the amount of melamine is about 35 g/m². The paper is a blue paper of 110 g/m². As can be seen from the picture, the cellulose fibers are well covered by micro-crystalline melamine, but the paper and melamine crystals has still a roughened structure to accommodate resin to easily be absorbed by the paper. It can be, that with other processes melamine will crystallize in another structure, and the present invention is not limited to the structure described herein.

In one embodiment, the paper is a continuous role of paper, which is drawn through a low pressure chamber for vapor deposition. Such role of paper generally will be several hundred meters, for example 500 m long or more, preferably 1 km or more. Generally, the length will be about 20 km or less, or about 10 km or less. Generally, the paper will have a width of 50 cm or more, preferably 1 m or more. Generally, the width will be about 8 m or less, or 6 m or less. In another embodiment, the paper may be leaves.

According one embodiment of the present invention, the paper with vapor deposited triazine is further impregnated with melamine-formaldehyde resin. In order to achieve optimal properties with respect to low formaldehyde emission and/or post-formability, it is preferred to use the melamine resin such that the impregnated paper exhibits certain characteristics as explained hereinafter.

Generally, melamine-formaldehyde (MF) resins are used to impregnate papers for laminates. These MF resins generally have a ratio of formaldehyde to melamine of about 1.7 to about 1.55. These values are achieved at ambient pressure synthesis at 55-65% solids, which is commonly used m practice. At a lower F/M ratio (formaldehyde to melamine) melamine does not any more dissolve (at normal pressure). Resins with higher F/M ratio's are useful as well, but the resultant laminates are relatively brittle, and therefore are not commonly used. If it were possible to use these higher ratio's F/M resins, one could improve the economics of the processes, because resin preparation would be shortened because the melamine dissolves faster.

In one embodiment of the invention, the MF resin used to impregnate the vapor-deposited triazine paper has a F/M ratio of about 1.5 or higher, the amount of resin is such that the impregnated paper—calculated with the amount of triazine deposited—has a theoretical FM ration of about 16 or lower, preferably, about 1.5 or lower, as such lower amounts lower formaldehyde emission, and improve post-formability. In general, the theoretical F/M ratio will be about 1 or higher, preferably about 1.1 or higher.

In one embodiment, it will be important to have most or all triazine dissolved during the curing (press) step. In order to have all triazine dissolved at a reasonable speed, it is preferred to have a F/M ratio of about 1.1 or higher; with somewhat longer press cycles, a ratio of about 1 may be effective. In case of melam, one mole of melam equalizes 1.33 mole of melamine in the theoretical F/M calculation. In this specification, F/M ratio is used, wherein the melamine can be in part, or completely be exchanged with another triazine, if one calculates the amount of melamine on paper, melam counts for 1.66 melamine, whereas acetoguanamine counts for about 0.66 melamine.

In another embodiment, the amount of melamine, and the curing process are chosen such that part of the melamine stays as solid. This is in particular useful in case white laminates are made, as in this way the color strength of white is improved.

In a further embodiment, the vapor deposited triazine paper is first impregnated with UF (urea-formaldehyde) resin, and dried, and thereafter with MF resin.

In another embodiment, the vapor-deposited triazine paper may be impregnated with a formaldehyde solution. In one embodiment, the F/M ratio is as in nowadays common ratio's like 1.5 to about 1.8. This has the advantage to obviate the resin manufacture, and current users of impregnated triazine papers do not have to adjust their current processes. In another preferred embodiment, the F/M ratio of the paper so obtained is as explained above (about 1.5 or lower). This may be preferred because if obviates the resin manufacture altogether, and it further the cured laminate exhibits lower formaldehyde emission and better post-forming characteristics.

Impregnating with an MF resin may be advantageous because the impregnation step can be more precise, and it is easily possible to have higher amounts of triazine loading than in conventional impregnated papers.

The melamine-formaldehyde resin can be made as known by the skilled person. Generally, melamine is added to a formaldehyde solution. Generally, the amount of formaldehyde is about 30 wt % or more in water. The amount of formaldehyde generally is about 40 wt % or less. The amount of melamine generally is about 30 wt % or more. Generally, the amount of melamine is about 50 wt % or less. Generally, a catalyst is present during the preparation of the resin. Suitable catalysts are organic or inorganic bases. Suitable bases include but are not limited to sodium hydroxide and potassium carbonate. It is further possible, to have plasticizers, extenders, flow promoters present or co-react with the melamine-formaldehyde resin. Suitable examples include, but are not limited to caprolactone, caprolactam, mono-, di-, or tri-ethylene glycol, mono, di and polyalcohols like butanediol, sorbitol and glucose, glycol-ethers like trioxytol, and urea or thiourea. Further, part of the melamine can be replaced by urea, to make a melamine-urea-formaldehyde resin (MUF). The term melamine-formaldehyde resin as used in this application comprises these variants. The resin can be catalyzed by acids. Suitable examples of acids include, but are not limited to para-toluenesulphonic acid.

Preferably, the amount of resin on the paper (counted as triazine as vapor deposit and the resin combined) is about 30 wt % or higher, preferably about 35 wt % or higher. Generally, the amount will be about 95 wt % or lower, or for example 90 wt % or lower. These weight percentages are calculated relative to the total weight of the paper plus triazine plus resin. Depending on the use, loadings can be different. For example, conventional overlay paper will preferably have a resin content of about 65 to 80 wt %. For example, conventional solid color paper may have a resin loading of about 45 to 55 wt %, and conventional printed paper can have a resin loading of about 35 to 45 wt %. The volatile content of the impregnated paper preferably is about 5-10 wt %.

With the products and process of the present invention, it is possible to obtain a higher amount of triazine per square meter than commonly obtained, in a very efficient way. With normal resin preparation and impregnation, it generally is possible to have paper with about 30 g/m² melamine on a light paper. With the current process, it is possible to arrive at substantial higher amounts of triazine like melamine per square meter, such as for example about 40 g/m² or more on a paper of 30 g/m². These papers if used for decorative laminates have better flow characteristics, and better post-forming characteristics. In case the high amount of triazine is combined with an F/M ratio of about 1.6 or lower, its formaldehyde emission characteristics are improved as well.

In one embodiment of the invention, the present invention provides for a B-stage melamine and MF resin comprising paper, in which the amount of melamine is about 0.8 g/m² per g/m² of paper, or more, preferably about 0.85 g/m² or more, and even more preferred, about 0.9 g/m² of melamine or more per g/m² of paper. Generally, the amount of melamine will be about 2 g/m² or less per g/m² of paper, for example about 1.2 g/m² or less. B-stage is generally used to mean an MF resin that has reacted to such an extent that a dry (to the hand) impregnated paper is obtained. Generally, this means that formaldehyde and melamine are reacted to at about 1:1. In conventional impregnated paper, this is about 5-10% reaction. The paper comprises generally about 5-15% water, to obtain a dried impregnated paper, which still shows flexibility.

The process according to the present invention for making a laminate comprises the following steps:
a) triazine is deposited on paper with vapor deposition,
b) the triazine-deposited paper is impregnated with s formaldehyde solution, or a melamine formaldehyde resin having an F/M ratio of 1.5 or higher,
c) in such amounts that the final F/M ratio is 1.6 or lower
d) submitting the paper with one or more other layers to pressure and/or sufficient temperature to cure the triazine and resin

In making laminates, it is also possible to use untreated sheets if the adjacent layers comprise sufficient resin, to have the non-treated impregnated during the press cycle, it is equally possible to use triazine-vapor deposited sheets, in case the adjacent sheet(s) comprise resin with sufficient formaldehyde to have all of a large part of the triazine reacted during the press cycle.

In another embodiment of the present invention, the process for making a laminate comprises the following steps:
a) triazine is deposited on paper with vapor deposition,
b) the triazine-deposited paper is laid adjacent to an impregnated sheet with a melamine formaldehyde resin having an F/M ratio of 1.5 or higher,
c) in such amounts that the composite F/M ratio is 1.6 or lower
d) submitting the papers with one or more other layers to pressure and/or sufficient temperature to cure the triazine and resin.

In another embodiment of the present invention, the process for making a laminate comprises the following steps:
a) triazine is deposited on paper with vapor deposition,
b) one or more layers of said triazine-deposited paper are laid in a press, together with one or more other layers to have a stack
c) said stack is subjected to pressure and/or sufficient temperature in the presence of such an amount of formaldehyde in the press, that triazine is converted into triazine-formaldehyde resin which is simultaneously cured.

In this embodiment, the step of making B-staged MF impregnated paper is altogether obviated. This has clear further advantages because a factory that makes cured laminates at present needs to be able to handle formaldehyde gas anyhow, in view of environmental concerns. Preferably, the formaldehyde gas is injected in the mold just before increasing the pressure.

In one embodiment of the invention, the other layers comprise kraft papers, impregnated with phenol-formaldehyde resin, and subjecting the stack to a pressure of about 30 N/m² or more, preferably 100 N/m² or more. Generally, the pressure will be about 150 N/m² or less. The temperature preferably in this HPL process is about 130° C. or more. Preferably, the temperature is about 220° C. or less, and in other embodiment 150° C. or less. Generally, the time used for curing will be generally about 2 to about 80 min.

In another embodiment, the other layer is a particle board, medium density fiber board, card board, and subjecting the stack to a pressure of about 20 N/m² or less. Generally, in this case of LPL, the temperature will be about 170° C. or higher. Generally, the temperature will be about 220° C. or lower. Generally, the time used for curing will be about 5 sec or more, for example 10 sec or more. Generally, the time used for curing will be about 120 sec or less, preferably about 60 sec or less, most preferred about 20 sec or less.

In one embodiment, the overlay paper contains hard abrasive mineral particles because with these, scratch and abrasion resistance can be improved. Generally, particles will have a size of about 50 nanometer or more, preferably about 30 micrometer or more. Generally, the size of the particles will be 200 micrometer or less, preferably about 150 micrometer or less. Particle with a size of 50 nanometer to 30 micrometer are for example suitable to improve scratch resistance. Particles with a size of 30 to 150 micrometer are for example suitable to improve abrasion resistance. Suitable examples of mineral particles include, but are not limited to silicon dioxide (silica), silicon carbide and aluminum oxide (corundum), of which aluminum oxide is preferred. The mineral particles may be present in the resin for impregnating the overlay paper. The particles may also be coated on the surface of the overlay paper after impregnating said paper. It is also possible to deposit the abrasive particles on the decorative paper, preferably after impregnating. In this embodiment, an overlay paper may not be necessary to achieve outstanding wear properties.

Preferred laminates have lower formaldehyde emission than conventional commercial laminates. Formaldehyde emission can be measured according EN 120 and according EN 717-1, -2, and -3.

The resultant laminates have good post-forming characteristics. This is in particular important for HPL, because these have to be attached to a substrate, and it is preferred, that the laminate can be bent if desired. However, post-forming characteristics are also useful with LPL, as it improves handling characteristics of the product, like with drilling, sawing and the like. Post-forming characteristics can be measured by EN438/2.1. The laminates of the present invention preferably pass said test, requiring to be able to bend the laminate over an edge that has ten times the thickness of the laminate.

The invention will be further elucidated by the following examples, without being limited thereto.

### EXAMPLES 1-5

### Vapor Deposition of Melamine on Paper:

Blue paper of 100 g/m² was put in a vacuum chamber. The vacuum chamber comprised a small oven with melamine. The paper was dried by applying a vacuum of 10⁻⁵ mbar, white having the temperature of the oven at 105° C. during 10 min. Thereafter, the weight of the dried paper was measured in order to be able to assess the amount of melamine deposited. The paper was put in the vacuum chamber, the melamine heated to 305° C. while the pressure was reduced to 10⁻⁵ mbar. During a certain time, melamine was deposited, as shown in table 1.

TABLE 1

| Example | Time side 1 | Time side 2 | Total melamine | Amount per m² |
|---|---|---|---|---|
| 1 | 10 min | — | 2.5 g | 37 |
| 2 | 3 min | — | 0.98 | 15.6 |
| 3 | 4 min | 4 min | 0.91 | 14.4 |
| 4 | 3 min | 3 min | 0.78 | 12.5 |
| 5 | 2 min 20 sec | 2 min 20 sec | 0.66 | 10.5 |

The amount of melamine deposited was negatively influenced by fouling of the oven and chamber. Therefore, the time necessary to achieve the required melamine deposition was increased from example 3 onwards. However, the examples show that melamine was successfully vapor deposited on paper, both on one side and on two sides, in amounts substantially larger than generally used in the process according to U.S. Pat. No. 6,832,518. It should also be noted, that these experiments are performed on laboratory equipment. On industrial scale, one can easily obtain high speeds (several seconds or less per meter) vapor deposition that would yield amounts as shown in this fable. SEM photographs were taken from papers 1 and 2.

### EXAMPLES 6-7 AND COMPARATIVE EXPERIMENT 1

### Resin Preparation

A melamine resin was made with an F/M ratio of 1.5 by reacting 956 g melamine with 924 (37%) formalin and 78 g di-ethylene glycol,, having added 542 g of wafer and sufficient 10% NaOH to achieve a pH of 9.3, at elevated temperature (about 100° C.). When the cloud point was reached, the water tolerance (WT) was tested. When the WT was 260%, the reaction mixture was quickly cooled to room temperature, and the pH was again adjusted to 9.3. To 990 g of this resin, 2 g wetting agent (Würtz 9594) and 2 g release agent (Würtz 2523W) was added. The pH now was 8.9, and the B-time was 304 sec. The resin was used as such. In case the B-time would have been larger, an amount of p-toluenesulphonic acid would have been added to arrive at a B-time of about 300 sec.

### Paper Impregnation

Papers 1 and 5 were used for impregnation and laminating. An untreated paper was used as a comparison. Papers (blue, 110 g/m²) were impregnated with 110% of a resin and dried in a Fresenberger oven at 100° C. for 9 min to achieve a resin with about 6% water. Paper 1 was impregnated on the side that was not having the melamine deposited, the paper curled so that the sides were out the resin. After full impregnation, the paper flattened again. All papers were well impregnated, both paper fibers and the melamine crystals. Melamine crystals were sufficiently firmly attached to the paper that they could withstand the impregnation step.

### Laminate Formation

Laminates were made by stacking one of the three layers on phenol-formaldehyde papers, suitable for post-forming. Laminates were pressed as described in EN 438 at a pressure of 8 MPa (=8 MM/m²). Post forming characteristics are measured as described in EN 438/2.1, requiring possibility to bend over a radius of 10 time the thickness of the laminate. The results are pass, when no cracks are observed, or fail, if the top layer shows defects

Results are shown in table 2

TABLE 2

| Example | Melamine | F/M ratio | Post-forming test |
|---|---|---|---|
| 6 (with paper 1) | 93.5 g/m² | 1.26 | Pass |
| 7 (with paper 5) | 88.5 g/m² | 1.33 | Pass |
| Comparative | 78.5 g/m² | 1.5 | Fail |
| experiment 1 with | | | |
| non-treated paper | | | |

These results show that at least part of the melamine did dissolve in the resin during cure, and that improved post-forming characteristics were obtained without the need of a special resin

1. Paper substrate comprising vapor deposited crystalline triazine, the amount of crystalline triazine being about 5 g/m² or higher, and about 100 g/m² or lower.

2. Paper substrate according to claim 1 wherein the triazine is melamine.

3. Paper substrate according to claim 1 wherein the triazine is melam.

4. Paper substrate according to claim 1 wherein the paper is deposited with a further triazine or a dye.

5. Paper according to claim 1, wherein the paper consists of non-woven and non-spun cellulose fiber.

6. Paper according to claim 1, wherein the paper has a weight of about 15 g/m² or more, and of about 200 g/m² or less.

7. Paper according to claim 1, wherein the paper is a decorative paper.

8. Paper according to claim 7, wherein the paper is unicolored.

9. Paper according to claim 7, wherein the paper has a print mimicking naturally occurring material.

10. Paper according to claim 1, wherein the paper is an overlay paper.

11. Paper according to claim 1, wherein the triazine is microcrystalline, having a platelet structure with a width of about 100 μm or less.

12. Process for making a paper according to claim 1, wherein paper is subjected to vapor deposition at one opening of a vacuum chamber, the speed of the paper over the vacuum chamber is about 0.5 m/s or more, and about 10 m/s or less, the triazine in the vacuum chamber has a temperature of about 250° C. or higher, preferably about 330° C. or higher, and the vacuum is about 10 Pa or less, and whereby the temperature of the paper substrate is 250° C. less than the temperature of the triazine.

13. Process for making a laminate comprising at least one cured layer of melamine-formaldehyde resin and a paper, wherein
a) triazine is deposited on paper with vapor deposition, to obtain a paper substrate comprising vapor deposited triazine,
b) the triazine-deposited paper is impregnated with a formaldehyde solution, or a melamine formaldehyde resin having an F/M ratio of 1.5 or higher,
c) in such amounts that the final F/M ratio is 1.6 or lower
d) submitting the paper with one or more other layers to pressure and/or sufficient temperature to cure the triazine and resin.

14. Process for making a laminate comprises the following steps:
a) triazine is deposited on paper with vapor deposition,
b) the triazine-deposited paper is laid adjacent to an impregnated sheet with a melamine formaldehyde resin having an F/M ratio of 1.5 or higher,
c) in such amounts that the composite F/M ratio is 1.6 or lower
d) submitting the papers with one or more other layers to pressure and/or sufficient temperature to cure the triazine and resin.

15. Process according to claim 14, wherein the impregnated sheet is an overlay paper, impregnated with about 65% or more MF resin.

16. Process for making a laminate comprises the following steps:
a) triazine is deposited on paper with vapor deposition,
b) one or more layers of said triazine-deposited paper are laid in a press, together with one or more other layers to have a stack of papers
c) said stack is subjected to pressure and/or sufficient temperature in the presence of such an amount of formaldehyde in the press, that triazine is converted into triazine-formaldehyde resin which is simultaneously cured.

17. Process according to claim 13, wherein the paper substrate with vapor deposited triazine is a paper according to Paper substrate comprising vapor deposited crystalline triazine, the amount of crystalline triazine being about 5 g/m² or higher, and about 100 g/m² or lower.

18. Process according to claim 13, wherein the triazine is deposited on the paper by a process for making a paper wherein paper is subjected to vapor deposition at one opening of a vacuum chamber, the speed of the paper over the vacuum chamber is about 0.5 m/s or more, and about 10 m/s or less, the triazine in the vacuum chamber has a temperature of about 250° C. or higher, preferably about 330° C. or higher, and the vacuum is about 10 Pa or less, and whereby the temperature of the paper substrate is 250° C. less than the temperature of the triazine.

19. B-stage triazine and MF resin comprising paper, in which the amount triazine, calculated as melamine is about 0.8 g/m² or more per g/m² of paper.

20. Paper according to claim 19, wherein the amount of triazine calculated as melamine is about 0.9 g/m² or more per g/m² of paper.

21. Paper according to claim 19, wherein the triazine is melamine.
